(19) United States
(12) Patent Application Publication
(10) Pub. No.: US 2015/0244147 A1
(43) Pub. Date: Aug. 27, 2015

(54) METHOD FOR PRODUCING A SEMICONDUCTOR LASER DIODE, AND SEMICONDUCTOR LASER DIODE

(71) Applicant: OSRAM Opto Semiconductors GmbH, Regensburg (DE)

(72) Inventors: Bernhard Stojetz, Wiesent (DE); Alfred Lell, Maxhuette-Haidhof (DE); Christoph Eichler, Tegernheim (DE)

(21) Appl. No.: 14/418,923

(22) PCT Filed: Jul. 29, 2013
(86) PCT No.: PCT/EP2013/065911

§ 371 Date: Jan. 30, 2015

(30) Foreign Application Priority Data
Jul. 30, 2012 (DE) 10 2012 106 943.3

(51) Int. Cl. H01S 5/10; H01S 5/343; H01S 5/323; H01S 5/028

(52) U.S. Cl. CPC H01S 5/1082; H01S 5/0287; H01S 5/028; H01S 5/343; H01S 5/32341

(57) ABSTRACT

A method for producing a semiconductor laser diode is specified, comprising the following steps:—epitaxial iv growing a semiconductor layer sequence (2) having at least one active layer (3) on a growth substrate (1)—forming a front facet (5) on the semiconductor layer sequence (2) and the growth. substrate (1), wherein the front facet (5) is designed as a main. emission surface having a light emission region (6) for the laser light (30) generated in the completed semiconductor laser diode,—forming a coupling-out coating (9) on a second part (52) of the front facet (5), wherein the first. part (51) and the second part (52) are arranged at least partly alongside one another in a direction parallel to the front facet (5) and along a growth direction of the semiconductor layer sequence (2), such that the first part (51) is at least partly free of the coupling-out coating (9) and the second part (52) is at least partly free of the light blocking layer (8), and wherein the second part (52) has the light exit region (6),—forming a light blocking layer (8) on a first part (51) of the front facet (5). Furthermore, a semiconductor laser diode is specified.

A method for producing a semiconductor laser diode, and a semiconductor laser diode are specified.

This patent application claims the priority of German patent application 10 2012 106 943.3, the disclosure content of which is hereby incorporated by reference.

In the case of edge emitting laser diodes, the carrier substrate or growth substrate of which is at least partly transparent to generated radiation, as is the case for example for blue- or green-emitting InGaN lasers on GaN substrates, stray light of the laser mode or spontaneously emitted light can propagate in the substrate. If said light emerges from the coupling-out facet, which can be referred to as substrate light emission, the beam quality of the emitted laser radiation decreases, since the radiation no longer emerges from a single, point-like region at the coupling-out facet and the ideal Gaussian emission characteristic of the laser is therefore disturbed. Particularly when such laser diodes are used in laser projectors with so-called flying spot technology, the disturbing emission from the substrate results in undesirable imaging aberrations in the projected image, for example by virtue of a disturbing, bright and unsharp image edge around the projected image. This undesirable, so-called “halo” effect is at odds with a high-resolution sharp imaging by laser projectors.

In the case of laser diodes on transparent GaN substrates, a dielectric reflective or antireflective coating of the coupling-out facet is usually effected, which is optimized in relation to the respective operating point, that is to say the output power sought, of the laser. As a result, however, the substrate light emission from the coupling-out facet is not blocked selectively with respect to the actual laser emission.

In order to suppress the emission from the substrate, it is known to apply a layer which blocks the undesirable radiation on the coupling-out facet above or below the reflective or antireflective coating of the coupling-out facet. Since adhesion problems can occur in the case of coatings on dielectric layers, which are usually used for reflective and antireflective coatings, applying such a radiation-blocking layer on the reflective or antireflective coating is critical and significantly restricts the choice of suitable materials and processes for a radiation-blocking layer. Furthermore, particularly if metallic materials for blocking radiation are applied directly to the semiconductor, there is the risk of migration-governed facet damage (COD: “catastrophic optical damage”) and/or a short circuit via the pn junction.

It is at least one object of specific embodiments to specify a method for producing a semiconductor laser diode. It is at least one further object of specific embodiments to specify a semiconductor laser diode.

These objects are achieved by means of an article and a method according to the independent patent claims.

Advantageous embodiments and developments of the article and of the method are characterized in the dependent claims and are furthermore evident from the following description and the drawings.

In accordance with at least one embodiment, a method for producing a semiconductor laser diode comprises a step which involves epitaxially growing a semiconductor layer sequence having at least one active layer on a growth substrate. The growth substrate can preferably be a transparent substrate that is transmissive to the light generated in the active layer during the operation of the semiconductor laser diode. Preferably, the growth substrate is formed by a GaN substrate. The epitaxial growth can be carried out for example by means of metal organic vapor phase epitaxy (MOVPE) or molecular beam epitaxy (MBE).

The semiconductor layer sequence is preferably based on a III-V compound semiconductor material. The semiconductor material is, for example, a nitride compound semiconductor material such as AlₓIn_{1-x-y}Ga_{y}N or a phosphide compound semiconductor material such as AlₓIn_{1-x-y}Ga_{y}P or else an arsenide compound semiconductor material such as AlₓIn_{1-x-y}Ga_{y}As, wherein in each case 0≦x≦1, 0≦y≦1 and x+y≦1. In this case, the semiconductor layer sequence can comprise dopants and additional constituents. For the sake of simplicity, however, only the essential constituents of the crystal lattice of the semiconductor layer sequence, that is to say Al, As, Ga, In, N or P, are specified, even if they can be replaced and/or supplemented in part by small amounts of further substances.

The semiconductor layer sequence comprises at least one active layer designed for generating electromagnetic radiation, that is to say in particular laser light in an ultraviolet to infrared wavelength range. The active layer comprises, in particular, at least one pn junction or, preferably, one or a plurality of quantum well structures. The laser light generated by the active layer during operation is, in particular, in the spectral range of between 380 nm and 550 nm inclusive or between 420 nm and 540 nm inclusive.

Alternatively, it is also possible for the growth substrate to be replaced by a carrier substrate that differs from the growth substrate. In this case, in the following embodiments, the growth substrate is to be replaced by the carrier substrate.

In accordance with a further embodiment, a further method step involves forming a front facet at the semiconductor layer sequence and the growth substrate. Shaping the front facet is preferably effected after epitaxially growing the semiconductor layer sequence onto the growth substrate. The front facet is produced, in particular, by virtue of the fact that the growth substrate on which the semiconductor layer sequence is applied is split up, for example by means of cleavage. It is likewise possible for the front facet to be produced by etching. A projection can then be formed at the growth substrate and/or at the semiconductor layer sequence. Furthermore, a rear-side facet can also be formed at a side of the semiconductor layer sequence and of the growth substrate that is situated opposite the front facet, for which purpose a method like that for producing the front facet can be used.

In particular, the semiconductor laser diode produced can be an edge emitting laser, for example a so-called stripe laser, a ridge waveguide laser, a trapezoidal laser or a combination thereof. In the case of such semiconductor laser diodes, the front facet and also the rear-side facet are formed by side surfaces of the semiconductor layer sequence and of the growth substrate, which are preferably arranged perpendicularly to the extension direction of the semiconductor layers of the semiconductor layer sequence. The active layer can comprise an active region, for example, which is formed by a part of the active layer and in which the laser light is generated. Depending on the embodiment of the semiconductor laser diode, the semiconductor layer sequence can thus have an active region comprising the entire or else only a part of the active layer. Furthermore, the semiconductor laser diode can be embodied as laser bar which has active regions in the active layers laterally alongside one another, that is to say in a direction parallel to the main extension plane of the active layer, via which active regions in each case laser light can be emitted during operation.

In accordance with a further embodiment, the front facet is designed as a main emission surface having a light emission region for the laser light generated in the completed semiconductor laser diode. This can mean, for example, that the front facet is designed as the only side of the semiconductor laser diode for emitting the light generated in the active region of the semiconductor layer sequence during operation. The front facet is preferably a smooth, planar area. An average roughness of the front facet is for example at most 100 nm and preferably at most 50 nm and particularly preferably at most 10 nm. The light emission region of the front facet denotes, in particular, that region of the front facet via which the desired laser light produced in the active region during the operation of the semiconductor laser diode is emitted intentionally, that is to say for example a region in which a fundamental mode of the laser light reaches the front facet. The light emission region is formed in particular by a partial zone of the semiconductor layer sequence and/or by a partial zone of the growth substrate near to the semiconductor layer sequence and is therefore situated in or near a region of the front facet in which the active region of the active layer is also situated.

In accordance with at least one embodiment, a semiconductor laser diode comprises a growth substrate, on which a semiconductor layer sequence having at least one active layer designed for generating laser light is applied.

In accordance with a further embodiment, the semiconductor laser diode comprises a front facet at the growth substrate and the semiconductor layer sequence, which is designed as a main emission surface having a light emission region for the laser light generated in the completed semiconductor laser diode.

The embodiments and features described above and below apply equally to the semiconductor laser diode and the method for producing the semiconductor laser diode.

In accordance with a further embodiment, a light blocking layer is formed on a first part of the front facet. The light blocking layer is designed to block or at least attenuate a part of the radiation generated in the completed semiconductor layer sequence during operation. That means that the light blocking layer is nontransmissive or at least not very transmissive or else greatly scattering for at least one part of the radiation generated in the active layer of the semiconductor layer sequence. A transmission for the light generated in the active layer through the light blocking layer is preferably at most 80%, preferably at most 10%, particularly preferably at most 1% or even at most 0.2%. It is also possible for the light blocking layer to be completely nontransmissive for the light generated in the active layer during the operation of the semiconductor laser diode. In particular, the light blocking layer preferably does not cover the light emission region. In other words, the first part of the front facet is not identical to the light emission region, such that despite the light blocking layer on the front facet the laser light generated in the active layer during the operation of the semiconductor laser diode can be emitted via the front facet and in particular the light emission region.

In accordance with a further embodiment, on a second part of the front facet, an optical coating, preferably a reflective or antireflective coating, is formed on a second part of the front facet. Hereinafter, the optical coating can also be designated as coupling-out coating, wherein the term coupling-out coating encompasses optical coatings having a desired antireflective coating effect and/or a desired partial reflective coating effect. By way of example, the coupling-out coating can be embodied as an antireflection coating or as a partial reflective coating. Furthermore, the term coupling-out coating can also encompass an optically inactive layer, for example a so-called lambda/2 coating. The coupling-out coating on the front facet thus has, in a purpose for the chosen manner, a reflectance and a transmittance for the laser light. In particular, the coupling-out coating is applied in the light emission region on the front facet, such that the optical coating covers the light emission region and in the latter provides for the desired reflection and transmission or coupling-out of the laser light generated in the active layer during operation.

In accordance with a further embodiment, one or a plurality of layers composed of a transparent dielectric material are applied as coupling-out coating, for example an oxide or nitride or oxynitride comprising one or a plurality selected from silicon, aluminum, titanium, tantalum, hafnium. Such optical coatings serving as reflective or antireflective coating are known to a person skilled in the art and will therefore not be explained further here.

The first part and the second part of the front facet, that is to say the part on which the light blocking layer is formed and the part on which the coupling-out coating is formed, are arranged at least partly alongside one another in a direction parallel to the front facet and along the growth direction of the semiconductor layer sequence. That means that the first part is at least partly free of the coupling-out coating and the second part is at least partly free of the light blocking layer, and that the second part has the light exit region. The light blocking layer and the coupling-out coating are thus arranged at least partly alongside one another at the front facet. Like the first and second parts of the front facet, therefore, the light blocking layer and the coupling-out coating at least partly do not overlap.

If the first part of the front facet and the second part of the front facet and thus the light blocking layer and the coupling-out coating overlap, then the coupling-out coating is preferably applied before the light blocking layer, such that the light blocking layer covers a part of the coupling-out coating. As a result, regardless of the material used for forming the light blocking layer, it is possible to avoid the formation of leakage currents during the operation of the semiconductor laser diode. Furthermore, it is also possible that the first and second parts do not overlap, with the result that the light blocking layer and the coupling-out coating are formed alongside one another on the front facet and do not cover one another.

In accordance with one preferred embodiment, a method for producing a semiconductor laser diode comprises the following steps:

epitaxially growing a semiconductor layer sequence having at least one active layer designed for generating laser light on a growth substrate,
forming a front facet on the semiconductor layer sequence and the growth substrate, wherein the front facet is designed as a main emission surface having a light emission region for the laser light generated in the completed semiconductor laser diode,
forming a coupling-out coating on a second part of the front facet, wherein the first part and the second part are arranged at least partly alongside one another in a direction parallel to the front facet and along the growth direction of the semiconductor layer sequence, such that the first part is at least partly free of the coupling-out coating and the second part is at least partly free of the light blocking layer, and wherein the second part has the light exit region,
forming a light blocking layer on a first part of the front facet.

In accordance with a further preferred embodiment, a semiconductor laser diode comprises the following features:

a growth substrate,
a semiconductor layer sequence on the growth substrate having at least one active layer designed for generating laser light,
a front facet at the growth substrate and the semiconductor layer sequence, which is designed as a main emission surface having a light emission region for the laser light generated in the completed semiconductor laser diode,
a light blocking layer on a first part of the front facet, and
a coupling-out coating on a second part of the front facet, wherein the first part and the second part are arranged at least partly alongside one another in a direction parallel to the front facet and along the growth direction of the semiconductor layer sequence, and wherein the second part has the light exit region.

In accordance with a further embodiment, the light blocking layer and/or the coupling-out coating are/is produced by means of directional methods. In this case, “directional” means that a material by means of which the light blocking layer or the coupling-out coating is shaped is applied from a specific direction or a narrowly defined direction range. The method can involve coating methods, for example, such as molecular beam epitaxy (MBE), vapor deposition, ion beam deposition or sputtering. In contrast thereto, non-directional coating methods are those in which a coating with a material is effected independently of an orientation of the area to be coated. Such coating methods in which no or only a comparatively low directional selectivity occurs are, for example, chemical vapor deposition (CVD), MOVPE and atomic layer deposition (ALD).

The techniques underlying the methods mentioned can also be suitable for implanting material at least partly or wholly into the front facet, that is to say into the growth substrate and/or into the semiconductor layer sequence. Furthermore, it can also be possible for material applied to the front facet to diffuse at least partly into the front facet, for example by means of a suitable heat treatment step.

Furthermore, additionally or alternatively, a roughening method, for example a mechanical roughening method or a chemical roughening method, can be used in particular for the purpose of forming the light blocking layer.

In accordance with a further embodiment, forming the light blocking layer and/or the coupling-out coating is carried out using a shading. In particular, by means of the shading, it is possible to carry out structured formation of the light blocking layer on the first part of the front facet and/or of the coupling-out coating on the second part of the front facet.

In accordance with a further embodiment, the shading when forming the light blocking layer and/or the coupling-out coating is carried out by a shading by means of dummy bars. Dummy bars are preferably arranged such that the growth substrate with the grown semiconductor layer sequence and the front facet formed is arranged between two dummy bars. That means, in particular, that the growth substrate with the grown semiconductor layer sequence is arranged between two dummy bars in the growth direction. Dummy bars used can be, in particular, a semiconductor material, for example a substrate, on which no semiconductor layer sequence having an active layer is deposited. In particular, no semiconductor laser diode is produced from a dummy bar.

In accordance with a further embodiment, the dummy bars project beyond the front facet in a direction perpendicular to the front facet. In other words, the dummy bars protrude beyond the front facet of the semiconductor layer sequence and of the growth substrate. Such an arrangement can make it possible that, in an oblique plan view of the front facet, one dummy bar of the two dummy bars, between which the growth substrate with the semiconductor layer sequence is arranged, shades the first part and the other dummy bar shades the second part of the front facet, such that, by means of directional methods performed obliquely with respect to the front facet, it is possible to form the light blocking layer on the first part and the coupling-out coating on the second part in a structured fashion.

In accordance with a further embodiment, at least one dummy bar has a projection, which covers either the first part or the second part of the front facet in a plan view of the front facet. The projection preferably extends in a direction parallel to an end side of the dummy bar. In particular, the projection can be spaced apart from the front facet. As a result, it can be possible that the first or second part is shaded by the projection, such that a directional or a non-directional method is used for forming the non-shaded part of the front facet. By virtue of the fact that the projection is spaced apart from the front facet, by means of a directional method that region of the front facet which is shaded by the projection in a plan view can also be accessible for forming the light blocking layer or the coupling-out coating.

In accordance with a further embodiment, for the purpose of forming the light blocking layer and the coupling-out coating, a plurality of growth substrates with in each case a grown semiconductor layer sequence together with a plurality of dummy bars are assembled to form a so-called rack, such that it is possible to carry out a simultaneous formation of the light blocking layer and of the coupling-out coating on the growth substrates with the semiconductor layer sequences assembled in a rack. That means that a plurality of growth substrates with in each case a grown semiconductor layer sequence and a plurality of dummy bars are arranged closely adjacent in a manner alternating from one another, that is to say alternately, wherein the front facets of the growth substrates with the semiconductor layer sequences preferably all face in the same direction.

If the dummy bars project beyond the front facets in a direction perpendicular thereto, this means in other words that on the side of the front facets the dummy bars project from the rack relative to the front facets.

In accordance with at least one embodiment, a method for forming the light blocking layer and/or a method for forming the coupling-out coating are/is oriented obliquely with respect to the front facets. That means that the direction in which the directional method is carried out has an angle of not equal to 90° with respect to the front facets. As a result, it is possible, as described above, that, during the process of forming the light blocking layer or during the process of forming the coupling-out coating, a shading is effected by a respective dummy bar.

In accordance with a further embodiment, all dummy bars in the rack have a projection described above.

In accordance with a further embodiment, the front facets, as seen directly in a plan view of the front facets, are not covered by the dummy bars. That means that, as seen in a direction perpendicular to the front facets, the complete front facets are freely accessible.

In the case of the method described here, it is thus advantageously possible that for a plurality of growth substrates with an applied semiconductor layer sequence in each case a light blocking layer and a coupling-out coating can be applied in parts of the respective front facet which are arranged at least partly alongside one another, wherein it is necessary for the growth substrates with the semiconductor layer sequences to be assembled in a rack only once. This makes it possible to eliminate an increased outlay during processing, required for example by repeated assembly in a rack, which is what is usually carried out when producing a plurality of structured layers on a facet. The dummy bars described here enable a partial formation of the coupling-out coating and of the light blocking layer in directly successive process steps without intervening rack transfer of the growth substrates with the semiconductor layer sequences. The formation of the light blocking layer and of the coupling-out coating is thus possible cost-effectively and in a large volume.

In accordance with a further embodiment, for the purpose of forming the light blocking layer in the first part a material which is reflective and/or absorbent for the light generated in the completed semiconductor laser diode is applied to the front facet. In particular, in this case, the light blocking layer can be formed as a coating on the front facet. Appropriate absorbent materials include, for example, metals, such as titanium, platinum, tungsten, nickel, palladium, chromium, aluminum and combinations thereof. Furthermore, semiconductor materials are suitable, which are applied as semiconductor layers along the front facet in the first part and which have a smaller band gap than the energy of the light generated in the semiconductor laser diode, for example silicon, germanium, AlₓIn_{y}Ga_{1-x-y}N, AlₓIn_{y}Ga_{1-x-y}As, AlₓIn_{y}Ga_{1-x-y}P (where x, y are in each case between 0 and 1), ZrO, ZnO, ZnSe, CdTe and combinations thereof. For the purpose of setting the absorption properties, the semiconductor material can also be doped.

In the case of a coating, the thickness of the light blocking layer can be at least 0.1 nm or at least 10 nm or else at least 50 nm and alternatively or additionally at most 10 μm or at most 2 μm or at most 1 μm.

In accordance with a further embodiment, for the purpose of forming the light blocking layer, a material which absorbs the light generated in the completed semiconductor laser diode is introduced at least into the growth substrate by implantation or diffusion in the first part of the front facet. By way of example, a material such as nitrogen, phosphorus, oxygen, magnesium, silicon, germanium, boron, hydrogen or combinations thereof can be suitable for this purpose.

In accordance with a further embodiment, the front facet has a roughening in the first part at least as part of the light blocking layer. For this purpose, the first part of the front facet can be roughened for the purpose of forming the light blocking layer. A damping effect can be achieved by such a partial roughening of the front facet, since the undesirable light which reaches the front facet in the first part, for example disturbing substrate light emission, is distributed over a larger angular range and/or is backscattered into the substrate.

In accordance with a further embodiment, the light blocking layer comprises a combination of a reflective and/or absorbent material on the front facet and/or an absorbent material implanted or diffused in the front facet and/or a roughening of the front facet in the first part.

In accordance with a further embodiment, the rear-side facet situated opposite the front facet is roughened in a part situated opposite the first part. By this means, too, it is possible to achieve a damping effect of, for example, an undesirable laser light mode guided in the substrate.

In accordance with a further embodiment, a highly reflective optical coating embodied as a resonator mirror for the laser light is applied at the rear-side facet in places or over the whole area.

In the case of the semiconductor laser diode described here, what can advantageously be achieved by means of the integration of the light blocking layer into or onto the front facet is that no external diaphragms or absorbent elements are required, which considerably reduces the assembly outlay and the assembly tolerance of the semiconductor laser diode. Furthermore, the design size can be reduced and the integration in a projector, for example, can thus be facilitated. The preferably directly successive application of the light blocking layer and of the coupling-out coating makes it possible to achieve a cost-effective production of the light blocking layer structure, in particular. The only partial application, that is to say the structured application, of the light blocking layer and of the coupling-out coating on different parts or regions of the front facet makes it possible to minimize adhesion problems of the chosen materials and also to reduce the risk of short circuits of the active layer.

Further advantages, advantageous embodiments and developments will become apparent from the exemplary embodiments described below in association with the figures.

In the figures:

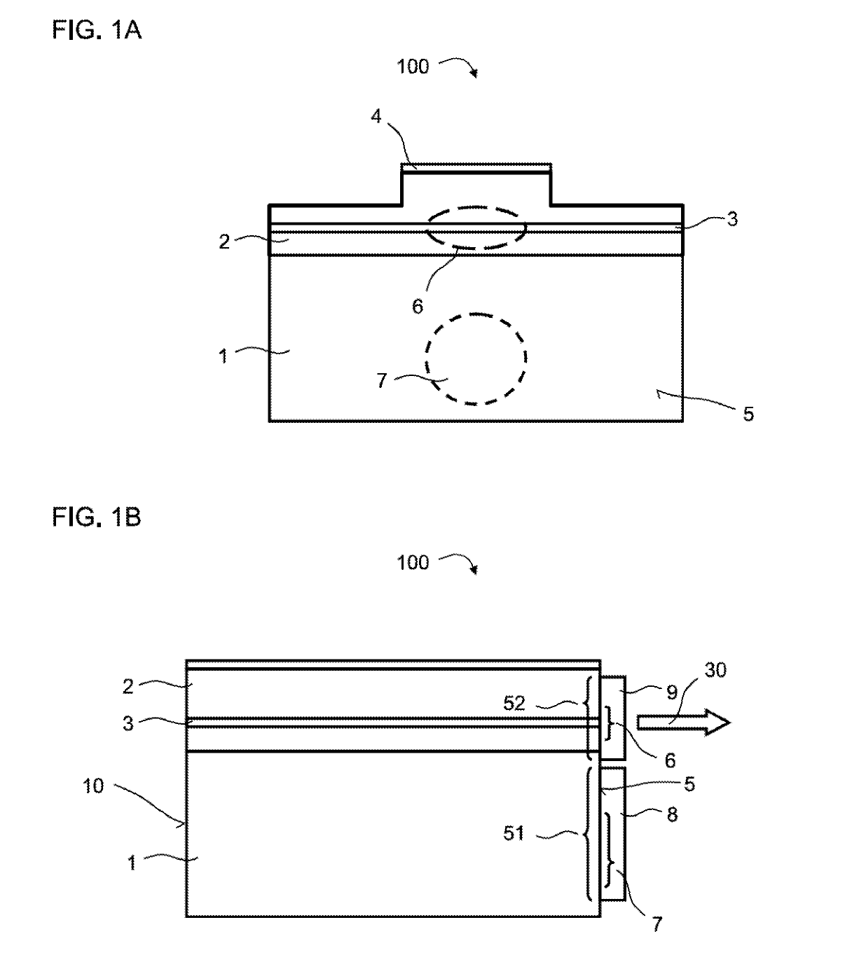

FIGS. 1A and 1B show schematic illustrations of a semiconductor laser diode in accordance with one exemplary embodiment,

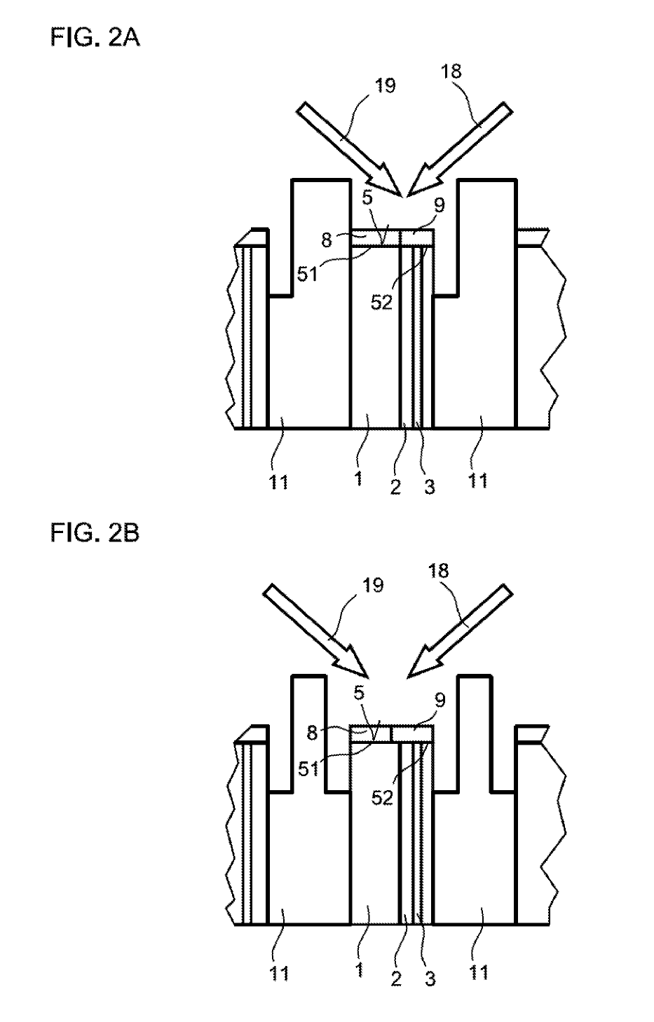

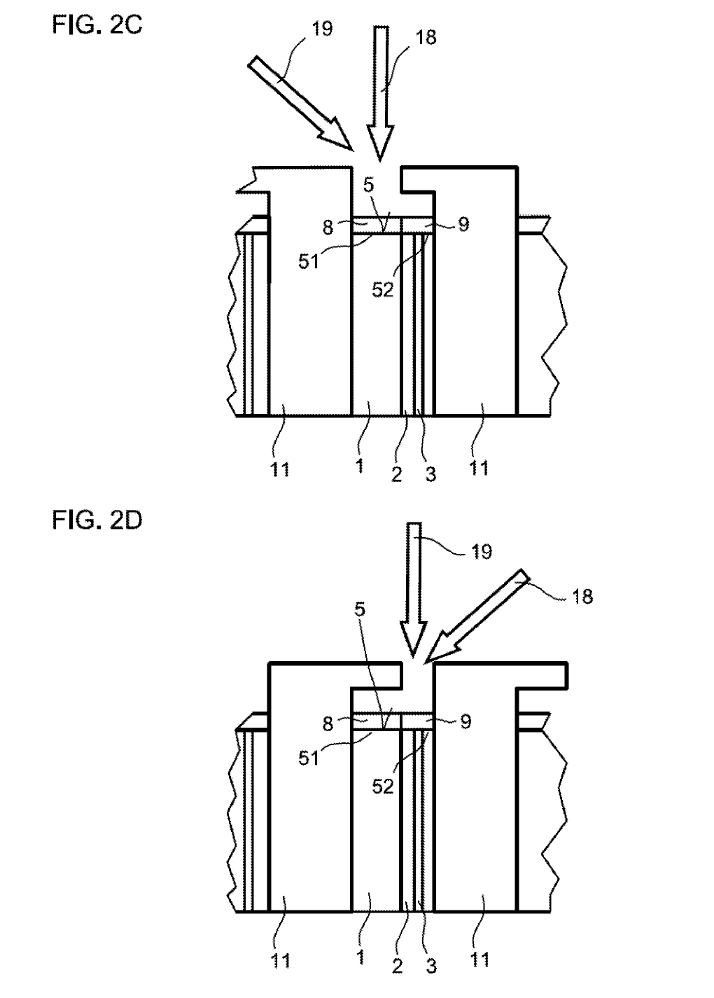

FIGS. 2A to 2D show schematic illustrations of methods for producing a semiconductor laser diode in accordance with further exemplary embodiments,

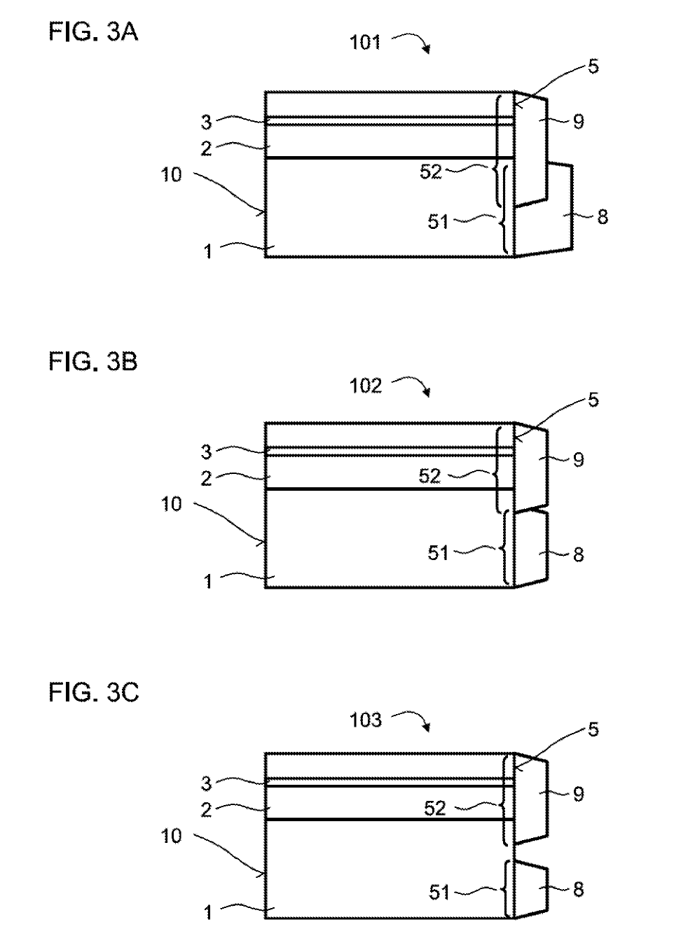

FIGS. 3A to 6 show schematic illustrations of semiconductor laser diodes in accordance with further exemplary embodiments.

In the exemplary embodiments and figures, elements that are identical, of identical type or act identically may be provided in each case with the same reference signs. The illustrated elements and their size relationships among one another should not be regarded as true to scale; rather, individual elements such as, for example, layers, structural parts, components and regions may be illustrated with an exaggerated size in order to enable better illustration and/or in order to afford a better understanding.

FIGS. 1A and 1B show one exemplary embodiment of a semiconductor laser diode 100, wherein FIG. 1A shows a plan view of the front facet 5 and FIG. 1B shows a sectional illustration through the semiconductor laser diode 100. In this case, the light blocking layer 8 and the coupling-out coating 9, which are shown in FIG. 1B, are not illustrated in FIG. 1A.

The semiconductor laser diode 100 comprises a substrate, which is preferably a growth substrate 1 for the semiconductor layer sequence 2 grown epitaxially thereon. As an alternative thereto, the substrate can also be a carrier substrate to which a semiconductor layer sequence 2 grown on a growth substrate was transferred after growth. Particularly preferably, the growth substrate 1 can be composed of GaN on which a semiconductor layer sequence 2 containing an AlInGaN compound semiconductor material is grown.

The semiconductor layer sequence 2 has an active layer 3 suitable for generating laser light 30 during operation. An electrode layer 4 provided for making electrical contact with the semiconductor layer sequence 2 is applied at a side of the semiconductor layer sequence 2 facing away from the growth substrate 1. The semiconductor laser diode 100 can comprise a further electrode layer for making electrical contact with the other side of the semiconductor layer sequence 2, which is not shown for the sake of clarity. The individual layers of the semiconductor layer sequence 2 in addition to the active layer 3, such as cladding layers, waveguide layers, barrier layers, current spreading layers and/or current limiting layers, are not shown in each case in order to simplify the illustration.

The semiconductor laser diode 100 shown can be a stripe laser, a trapezoidal laser, a ridge waveguide laser or a combination thereof. Furthermore, the semiconductor laser diode 100 can also be embodied as a laser bar.

The laser light 30 generated during the operation of the semiconductor laser diode 100 emerges at the front facet 5, which, as described in the general part, is formed after the growth of the semiconductor layer sequence 2 on the growth substrate 1 at the growth substrate 1 and the semiconductor layer sequence 2, in a light emission region 6. The light emission region 6 comprises a region at the front facet 5 which preferably corresponds to an exit area of the laser mode generated in the semiconductor layer sequence 2. The light emission region 6 is situated, in particular, opposite a region at a rear-side facet 10 of the growth substrate 1 and the semiconductor layer sequence 2 on which an optical coating in the form of a resonator mirror is applied (not shown).

On account of spontaneous emission, on account of stray radiation and/or on account of an overlap of an electric field of the laser mode with the substrate 1, light outside the actual desired laser mode of the laser light 30 can pass into the growth substrate 1. This light can also be designated as substrate mode. If the laser light 30 is blue or green light, then GaN, in particular, which is transparent to the laser light 30, is used as growth substrate 1, as described above. As a result, it is possible that light of the substrate mode can propagate substantially in an unimpeded fashion in the growth substrate 1.

Said light, if it reaches the front facet 5, can be emitted via a secondary emission region 7.

The secondary emission region 7 can have a comparatively large area proportion in comparison with the light emission region 6. In other words, the growth substrate 1 can then itself appear luminous and impair the beam quality of the actual desired laser radiation 30 emitted via the light emission region 6. If a semiconductor laser diode such as is shown in FIG. 1A is used without further measures for example in the context of a flying spot application for projection, then a so-called “halo” can form around a projection region, as a result of which the image quality can be significantly impaired.

In order to avoid the generation of such a halo as a result of the emission of undesirable light via the secondary emission region 7, on the front facet 5 a light blocking layer 8 is formed in a first part 51 of the front facet 5, as shown in FIG. 1B. The light blocking layer 8 is at least partly nontransmissive for light having the wavelength of the laser light 30. In other words, the light blocking layer 8 prevents the substrate mode described above from being able to leave the growth substrate 1.

Furthermore, an optical coating in the form of a coupling-out coating 9 is applied on the front facet 5 in a second part 52 comprising the light exit region 6. The coupling-out coating 9 has suitable optical properties in order to couple out a desired portion of the laser light 30 generated in the active layer 3. The antireflection coating 9 can thus have desired reflective and/or antireflective coating properties and/or an optically inactive lambda/2 coating. The coupling-out coating 9 can have for example one or a plurality of dielectric layers which are transparent and each have a suitable refractive index in order to achieve a desired reflective or antireflective coating effect.

The light blocking layer 8 and the coupling-out coating 9 are in each case not formed over a large area on the front facet 5, but rather are at least partly arranged alongside one another, such that the first part 51 is at least partly free of the coupling-out coating 9 and the second part 52 is at least partly free of the light blocking layer 8. The light blocking layer 8 and the coupling-out coating 9 are thus at least partly arranged alongside one another. In particular, the light blocking layer 8 and the coupling-out coating 9 do not overlap in the exemplary embodiment shown.

Further features, properties and arrangement possibilities for the light blocking layer 8 and the coupling-out coating 9 are described in association with FIGS. 3A to 6, while different method steps for forming the light blocking layer 8 and the coupling-out coating 9 are shown in association with FIGS. 2A to 2D.

For this purpose, a plurality of growth substrates 1 with grown semiconductor layer sequences 2, at each of which a front facet 5 was formed, together with a plurality of dummy bars 11 in an alternating arrangement are assembled in a so-called rack. In this case, the dummy bars 11 preferably project beyond the front facets 5 in a direction perpendicular to the front facets 5. As a result, a shading of regions of the front facet 5 arises at certain angles, wherein said angles can preferably be not equal to 90°. At a respectively suitable angle, therefore, for a directional method, therefore, it is possible for only the first part 51 or the second part 52 of the front facet 5 to be accessible.

As is shown in FIG. 2A, the dummy bars 11 can be structured such that they are spaced apart from the semiconductor layer sequence 2 in the region of the front facet 5. At the growth substrate 1, by contrast, the dummy bars 11 are arranged directly at the front facet 5. As a result, it is possible that a larger first part 51 in comparison with a smaller second part 52 of the front facet 5 is shaded on the side of the growth substrate 1.

A directional method, for example a directional coating method, is used in each case for forming the light blocking layer 8 and the coupling-out coating 9. The coating is effected here from a respective coating direction 18, 19, which, in the exemplary embodiment in FIG. 2A, are in each case at an angle with respect to the front facet 5 that is not equal to 90°. By way of example, the methods mentioned above in the general part can be used as directional coating methods. The light blocking layer 8 and the coupling-out coating can be arranged alongside one another in a partly overlapping fashion or else in a non-overlapping fashion, as is shown in the exemplary embodiments in FIGS. 3A to 6.

In accordance with the exemplary embodiment in FIG. 2B, the dummy bars 11 are structured on both sides, such that the dummy bars 11 adjoining the growth substrates 1 are in each case likewise arranged in a manner spaced apart from the front facet 5 at the growth substrate 1. As a result, it can be possible that the first and second parts of the front facet can be chosen to be of identical size, for example, since in the case of a symmetrical structuring of the dummy bars 11 and coating directions 18, 19 at identical angles it is also possible to achieve a symmetrical shading and thus a symmetrical structuring of the light blocking layer 8 and of the coupling-out coating 9.

In the exemplary embodiment in FIG. 2C and also in the exemplary embodiment in FIG. 2D, the dummy bars 11 in each case have a projection, which covers the first and respectively the second part of the front facet 5 in a plan view of the front facet 5 and is spaced apart from the front facet.

In the exemplary embodiment in FIG. 2C, as a result, the first part 51 of the front facet 5 is freely accessible in a plan view of the front facet 5 in a direction perpendicular to the front facet 5, such that a directional method with a coating direction 18 perpendicular to the front facet 5 can be carried out for forming the light blocking layer 8 in the first part 51 of the front facet 5, while the coupling-out coating 9 can be formed by means of a directional method with a coating direction 19, forming an angle not equal to 90° with the front facet, in the second part 52 of the front facet 5 below the projection of a dummy bar 11. This is exactly the opposite in the exemplary embodiment in FIG. 2D.

By means of a suitable combination of dummy bars 11, if appropriate having a structuring, and directional or non-directional methods for forming the light blocking layer 8 and the coupling-out coating 9, the light blocking layer 8 and the coupling-out coating 9 can be formed successively, preferably directly successively, in the same rack without rack transfer.

FIGS. 3A to 6 show further exemplary embodiments of semiconductor laser diodes 101, . . . , 111 which can be produced by means of the methods described above. The semiconductor laser diodes 101, . . . , 111 are based on the semiconductor laser diode 100 explained in FIGS. 1A and 1B, and so now not all elements are provided with reference signs in FIGS. 3A to 6, for the sake of clarity.

FIG. 3A shows a semiconductor laser diode 101 comprising on the front facet 5 a light blocking layer 8 and a coupling-out coating 9, which overlap. In other words, the first part 51 of the front facet 5 and the second part 52 of the front facet 5 overlap, in which the respective layer is applied. Furthermore, however, the light blocking layer 8 is partly not applied in the second part 52 and the coupling-out coating 9 is partly not applied in the first part 51 of the front facet 5. The coupling-out coating 9 covers the semiconductor layer sequence 2 on the front facet 5 and also a part of the growth substrate 1. The light blocking layer 8 covers a part of the growth substrate 1 and also a part of the coupling-out coating 9. What can be achieved as a result is that the light blocking layer 8 can be applied to a comparatively large part of the front facet 5, without there being a risk of leakage currents via the active layer 3.

In the exemplary embodiment shown, the light blocking layer 8 comprises an absorbent material, for example a metal such as titanium, platinum, tungsten, nickel, palladium, chromium, aluminum or combinations thereof. Alternatively or additionally, the light blocking layer 8 can also be formed by a semiconductor material in the form of one or a plurality of semiconductor layers, which material has a smaller band gap in comparison with the laser light generated in the active layer, for example Si, Ge, AlInGaN, AlInGaAs, AlInGaP, ZrO, ZnO, ZnSe, CdTe and combinations thereof.

In this case, it is not necessary for the light blocking layer 8 to have an exactly identical thickness across its entire extent. Furthermore, it is also not necessary for the light blocking layer 8 to have an exactly identical material composition across its entire extent. The thickness and the material composition, which can vary locally, merely have to be chosen in such a way that the light blocking layer 8 covers a sufficiently large part 51 of the front facet 5 and is nontransmissive or substantially nontransmissive for light emitted via the secondary emission region 7. By way of example, in a manner governed by production engineering, an edge of the front facet 5 can be free of the light blocking layer 8 all around.

The method in accordance with the previous exemplary embodiments can be demonstrable by an analysis of the deposition regions of the coupling-out coating 9 and of the light blocking layer 8 on the front facet 5.

FIG. 3B shows a further exemplary embodiment of a semiconductor laser diode 102, wherein the first and second parts 51, 52 and thus also the light blocking layer 8 and the coupling-out coating 9 overlap only in a small portion in comparison with the exemplary embodiment in FIG. 3A.

FIG. 3C shows a further exemplary embodiment of a semiconductor laser diode 103, wherein, in comparison with the two previous exemplary embodiments, the first and second parts 51, 52 are arranged alongside one another in a non-overlapping fashion on the front facet 5, such that the light blocking layer 8 and the coupling-out coating 9 also do not overlap or cover one another.

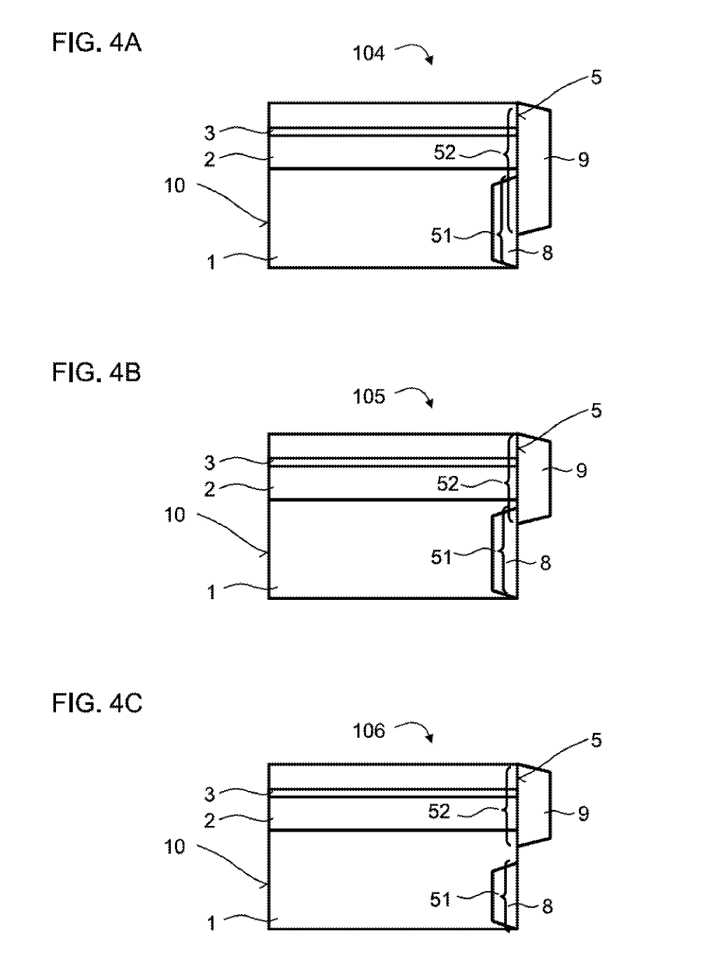

FIGS. 4A to 4C show further exemplary embodiments of semiconductor laser diodes 104, 105, 106 comprising a light blocking layer 8 and a coupling-out coating 9 which significantly overlap (FIG. 4A), overlap only in a small portion (FIG. 4B) or are arranged alongside one another in a non-overlapping fashion (FIG. 4C). In comparison with the previous exemplary embodiments in FIGS. 3A to 3C, the light blocking layer 8 is produced by an implantation or diffusion technique in the exemplary embodiments in FIGS. 4A to 4C. For this purpose, a suitable absorbent material, for example N, P, O, Mg, Si, Ge, B, H or combinations thereof, can be applied or introduced into the front facet 5, in particular into the growth substrate 1 at the front facet 5, in accordance with the methods described above.

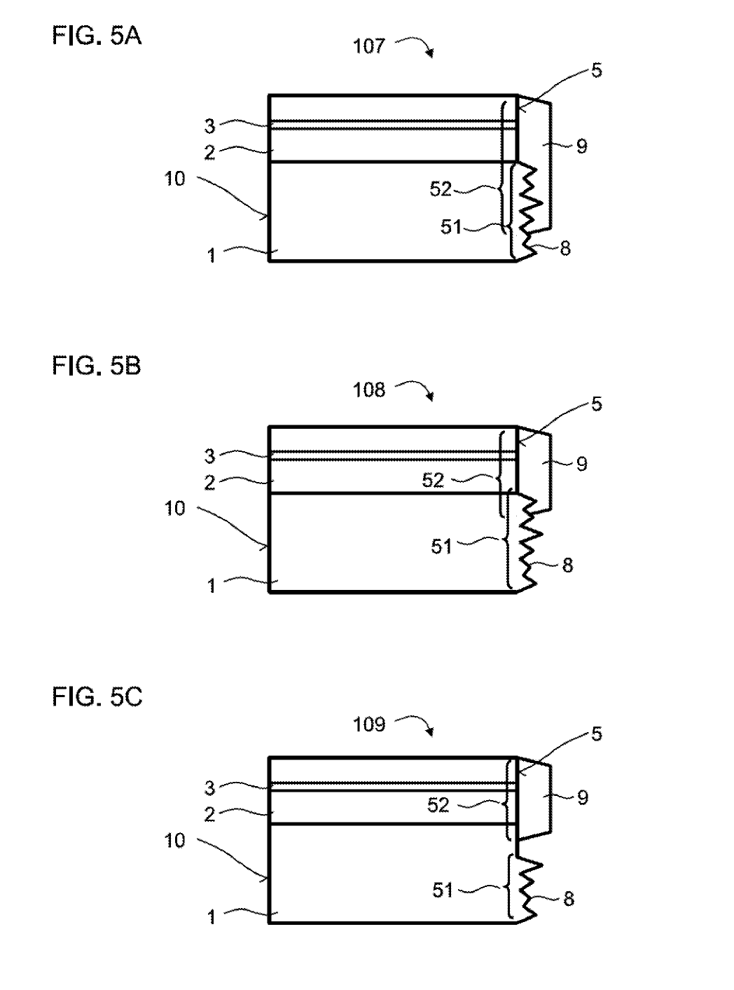

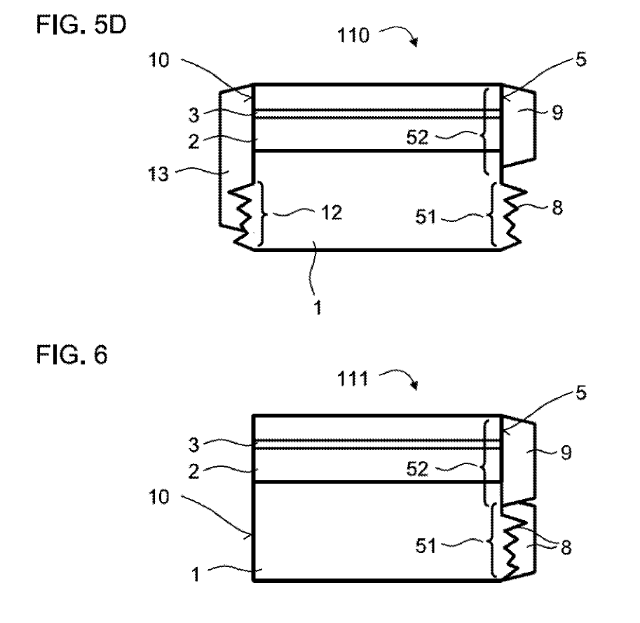

FIGS. 5A to 5D show further exemplary embodiments of semiconductor laser diodes 107, 108, 109, 110, which likewise comprise a light blocking layer 8 embodied in a manner overlapping a coupling-out coating 9 to different extents in accordance with FIGS. 5A to 5D. In comparison with the previous exemplary embodiments in FIGS. 3A to 4C, the light blocking layer 8 is embodied as a roughening on the front facet 5 in the first part 51 in the exemplary embodiments in FIGS. 5A to 5D. A damping effect can be achieved by means of such a partial roughening of the front facet 5, as a result of which the substrate mode can be distributed over a larger angular range and/or backscattered into the substrate 1. The roughening can be produced by directional etching methods, for example.

The semiconductor laser diode 110 shown in FIG. 5D comprises, in addition to the light blocking layer 8 embodied as a roughening on the front facet 5, a roughening on the rear-side facet 10 in a part 12 situated opposite the first part 51 on the front facet 5. Such a roughening on the rear-side facet 10 can be used for example for improving the adhesion of a highly reflective coating 13, usually in the form of a multilayered highly reflective mirror.

FIG. 6 shows a further exemplary embodiment of a semiconductor laser diode 111, which comprises a light blocking layer 8 formed by a combination of a roughening and an absorber material applied in the form of a coating. Both the roughening and the coating for forming the light blocking layer 8 can be produced by means of directional methods in accordance with the methods described above.

Furthermore, other combinations of the features described in the figures and also in the embodiments in the general part are also possible, even if they are not explicitly shown in the figures.

The invention is not restricted to the exemplary embodiments by the description on the basis of said exemplary embodiments. Rather, the invention encompasses any novel feature and also any combination of features, which in particular includes any combination of features in the patent claims, even if this feature or this combination itself is not explicitly specified in the patent claims or exemplary embodiments.

1. A method for producing a semiconductor laser diode comprising the following steps:
epitaxially growing a semiconductor layer sequence having at least one active layer on a growth substrate,
forming a front facet on the semiconductor layer sequence and the growth substrate, wherein the front facet is designed as a main emission surface having a light emission region for the laser light generated in the completed semiconductor laser diode,
forming a light blocking layer on a first part of the front facet,
forming a coupling-out coating on a second part of the front facet, wherein the first part and the second part are arranged at least partly alongside one another in a direction parallel to the front facet and along a growth direction of the semiconductor layer sequence, such that the first part is at least partly free of the coupling-out coating and the second part is at least partly free of the light blocking layer, and wherein the second part has the light exit region.

2. The method according to claim 1, wherein the front facet is roughened in the first part for the purpose of forming the light blocking layer.

3. The method according to claim 1, wherein a material which reflects and/or absorbs the light generated in the completed semiconductor laser diode is applied to the front facet in the first part for the purpose of forming the light blocking layer.

4. The method according to claim 1, wherein
the light blocking layer and/or the coupling-out coating are/is produced by means of directional methods, and
forming the light blocking layer and the coupling-out coating is carried out in each case by means of shading by means of dummy bars, between which the growth substrate with the grown semiconductor layer sequence is arranged in the growth direction, in a structured fashion and without rack transfer.

5. The method according to claim 4, wherein the dummy bars project beyond the front facet in a direction perpendicular to the front facet.

6. The method according to claim 4, wherein at least one dummy bar has a projection, which covers either the first part or the second part of the front facet in a plan view of the front facet and is spaced apart from the front facet.

7. The method according to claim 4, wherein, for the purpose of forming the light blocking layer and the coupling-out coating, a plurality of growth substrates with in each case a grown semiconductor layer sequence together with a plurality of dummy bars are assembled to form a rack.

8. The method according to claim 1, wherein the first part and the second part do not overlap.

9. The method according to claim 1, wherein, for the purpose of forming the light blocking layer, a material which absorbs the light generated in the completed semiconductor laser diode is introduced at least into the growth substrate by implantation or diffusion in the first part of the front facet.

10. A semiconductor laser diode, comprising
a growth substrate,
a semiconductor layer sequence on the growth substrate having at least one active layer designed for generating laser light,
a front facet at the growth substrate and the semiconductor layer sequence, which is designed as a main emission surface having a light emission region for the laser light generated in the completed semiconductor laser diode,
a light blocking layer on a first part of the front facet, and
a coupling-out coating on a second part of the front facet, wherein the first part and the second part are arranged at least partly alongside one another in a direction parallel to the front facet and along the growth direction of the semiconductor layer sequence, such that the first part is at least partly free of the coupling-out coating and the second part is at least partly free of the light blocking layer, and wherein the second part has the light exit region.

11. The semiconductor laser diode according to claim 10, wherein the first part and the second part do not overlap.

12. The semiconductor laser diode according to claim 10, wherein the front facet has a roughening in the first part at least as part of the light blocking layer.

13. The semiconductor laser diode according to claim 12, wherein a part situated opposite the first part of a rear-side facet situated opposite the front facet is roughened.

14. The semiconductor laser diode according to claim 10, wherein, at least as part of the light blocking layer, a material which reflects and/or absorbs the light generated in the completed semiconductor laser diode is applied in the first part of the front facet.

15. The semiconductor laser diode according to claim 10, wherein, at least as part of the light blocking layer, a material which absorbs the light generated in the completed semiconductor laser diode is introduced at least into the growth substrate by implantation or diffusion in the first part of the front facet.

16. A method for producing a semiconductor laser diode comprising the following steps:
epitaxially growing a semiconductor layer sequence having at least one active layer on a growth substrate,
forming a front facet on the semiconductor layer sequence and the growth substrate, wherein the front facet is designed as a main emission surface having a light emission region for the laser light generated in the completed semiconductor laser diode,
forming a light blocking layer on a first part of the front facet, wherein the front facet is roughened in the first part and a material which reflects and/or absorbs the light generated in the completed semiconductor laser diode is applied to the front facet in the first part,
forming a coupling-out coating on a second part of the front facet, wherein the first part and the second part are arranged at least partly alongside one another in a direction parallel to the front facet and along a growth direction of the semiconductor layer sequence, such that the first part is at least partly free of the coupling-out coating and the second part is at least partly free of the light blocking layer, and wherein the second part has the light exit region.
